(19) United States
(12) Patent Application Publication
(10) Pub. No.: US 2007/0034501 A1
(43) Pub. Date: Feb. 15, 2007

(54) Cathode-arc source of metal/carbon plasma with filtration

(76) Inventor: Efim Bender, Netania (IL)

Correspondence Address: Efim Bender, 19/24 Amnon Vetamar St., Netania, 42202, IL

(21) Appl. No.: 11/235,747

(22) Filed: Sep. 28, 2005

(30) Foreign Application Priority Data
Aug. 9, 2005 (IL) 170170

(51) Int. Cl. C23C 14/32; C23C 14/00

(52) U.S. Cl. 204/192.38; 204/298.41

(57) ABSTRACT

The a cathode-arc source of metal plasma with filtration, used, in particular, for deposition of DLC, utilizes the effect of fast ions reflection from the Hall stratum in a transversal arched magnetic field to filtrate vacuum arc plasma arc from contaminating macroparticles and vapor. Various embodiments for producing maximal plasma flux at the source outlet, in particular, a pulse source with more the one cathode units for deposition of coating inside pipes/cavities, for deposition of coating in a stationary/quasi-stationary condition are offered. The cathode is made of a consumable material and is exposed to poles of magnets on both ends of cathode for creating a transversal magnetic field of an arched configuration in a discharge gap between the cathode and the anode. The anode geometry adequate to the mechanism of the arc current passage through a transversal magnetic field is offered. To avoid longitudinal and transverse short circuits of the current layer, an installation of non-conducting surfaces at ends or sectioned shields under a floating potential at the cathode sides is provided. The method of creating the Hall stratum in said transversal magnetic field of arched configuration is offered.

### BACKGROUND OF THE INVENTION

The present invention relates to an ion source of plasma, and, in particular, to ion sources of plasma with filtration, for use in various application of ion fluxes, where an effective filtration of macroparticles by ions is required.

The vacuum arc produces a great number of ions from cathode material. The ion flux totals about 10% of the arc electron current. Ions can be governed on their path from the cathode to receiving surface by means of changing their trajectory and the surface bombardment energy.

The ions, generated in a vacuum arc, have high ‘natural’ kinetic energy in the range of 20-100 eV that provides favorable conditions for the process of ion deposition and even penetration of ions into internal substrata.

However, vacuum arcs generate usually undesirable macroparticles too (particles of cathode material, having a size of one micron), which, if not filtered from the plasma flux, result in a surface defects.

Vapor in certain conditions can also reduce the surface quality.

Separation or elimination of macroparticles and vapor from the ion flux, produced by an arc discharge, was an object of numerous studies for a long time [1-5].

Many devices have been developed, which enable separation of arc plasma from macroparticles by using various filtering systems: mechanical, electrostatic, magnetic.

Though many of these filters ensure producing of surfaces completely free of macroparticles and vapor, however, unfortunately, not only macroparticles but the most part of ion flux of the cathode material as well are captured by the filters. The filters are characterized by plasma transport efficiency K_{ef}, which is defined as ratio of output ion number to the number of ions at the filter's inlet. Frequently, it is hard to determine the ion flux at the filter's inlet, therefore it seems more reasonable to use a system coefficient Kₛ, which is defined as a ratio of the output ion flux I_{ic} to the arc current I_{arc}. The coefficient Kₛ characterizes not a filter but a system of the arc source and a filter.

The magnetic filters with a slightly bent longitudinal magnetic field are the most commonly used.

In these filters, electrons are magnetized and the Larmor radius of ions is by far larger than the filter size. The plasma flux is moving along a bent magnetic field due to limitation of transverse shift of electrons by a magnetic field. Ions are held in a bent flux by the polarized transverse electric field occurred during their shift relative to a stable population of electrons [6, 7]. The magnetic field does not affect motion of neither macroparticles nor vapor, as a result of this they are separated from the ion flux.

In majority of available magnetic filters, the plasma transport efficiency K_{ef} is only about 10%, and thus the system coefficient Kₛ is about 1%.

The Aksenov's rectilinear filter equipped with two solenoids is the simplest solution in the field of micro-droplet separators. The first solenoid forms a magnetic field in the near-to-cathode area, and the second one forms a magnetic field in the interelectrode space.

Application of a specific configuration of magnetic field, executing a so-called “magnetic pinch”, enables a considerable reduction of microdroplets number, but does not impede the particles completely [8].

A plasma channel in the form of quarter torus, developed by I. Aksenov, is one of the most often used in practice, which provides almost complete elimination of microdroplets from the plasma flux [9].

During the last 25 years a whole gamma of modifications of this type of filters, installed both inside and outside the vacuum chamber, have been developed. For example in work [10] there was used either so-called Knee-Filter with plasma flux bend to 45°, or a filter with plasma flux bend to 90° [11], or a double bent solenoid filter [12].

Systems with a dome magnetic field [13], as well as with a magnetic mirror [14], enable an almost complete elimination of microdroplets from the plasma flux.

Separation of microdroplets is also executed in systems with magnetic island. The electromagnet is arranged in a tubular plasma inlet on axis of the source enclosed in a housing made of nonmagnetic material; the electromagnet has a cross-sectional area, which is sufficient to let the target be beyond the sight from cathode. The magnetic field shape in these separators is selected in that way to provide the plasma's pass between the electrodes [15].

In all above mentioned systems a significant decrease in the ion current density of the plasma flux after its flow through the filter takes place. The system coefficient is typically about 1%. This result can be improved by using an additional anode located at some distance from the arc source cathode. This embodiment enables almost a double increase in the ion current density on outlet from the filter and, as a result, a considerable increase in coating deposition rate. But also in this case the system coefficient is typically about 2% [16].

In the U.S. Pat. No. 5,902,462 [17] it was offered to use a plasma source with a transversal magnetic field for turn of plasma stream of on 90°. However all plasma stream in this case is lost due to leaving plasma along a magnetic field in lateral areas of a source. It was observed in work [19].

As for small-sized sources of plasma with filtration, which enable to produce deposition inside the tubes and small cavities, to present day they do not exist.

Therefore an effective small-sized source of filtered cathodic arc plasma with transversal arched magnetic field is of barest necessity.

The opportunity realization of the offered method of the plasma stream filtration in the transverse arched magnetic field is grounded on the substantially observed the early experimental facts [18, 19]:
On the plasma boundary exist a Hall stratum wherein electrons is drifting in the crossed fields from the cathode to the anode.
The voltage on a discharge gap is 60-100V while without a magnetic field or in a longitudinal magnetic field it is equal 20-25V
The positively ionized atoms moving from cathode spot with energy 20-100 eV, are reflected from boundary of plasma.
Cathode spots are localized on the cathode surface on one line along a magnetic field and at such arrangement all together make retrograde remove across a magnetic field.

For explaining an electron current passage from the cathode 4 (FIG. 1A, FIG. 1B) to anode 6 in a weak magnetic field with magnetized electrons, the Hall current layer model was suggested [19]. A space between electrodes in the arc diffusion area in vacuum is filled with plasma generated with the cathode spots 5. In the collisionless region, the magnetized electrons can move across the magnetic field to the anode as a result of a drift in the intersected fields. Such a drift can be realized at the plasma boundary 7 where formation of an electric field normal to the boundary is possible. In a weak magnetic field, the fast ions are moving nearly linearly.

At their attempt to escape through the plasma boundary (because of violation of neutrality) an electric field E is excited and maintained in the near-the-boundary layer, which keeps the fast ions. In this a layer, an electron drift v_{dr}=E/B, where B is a magnetic field in the near-boundary layer.

The arc electron beam current Iₑ is provided by the flux of electrons drifting along the near-boundary layer, which is called the Hall layer.

In the homogeneous magnetic field with a spherically symmetric propagation of fast ions from the cathode spot into the spatial angle 2π the layer configuration in a plane perpendicular to a magnetic field is featured by the equation of a cardioid in the form[18] (FIG. 1B):

$$r = {r}_{o} {sin}^{2} \frac{α}{2} , \\ ð {er}_{o} = \frac{1}{\sqrt{2}} {k}_{r} {K}_{i} \frac{\sqrt{M {W}_{i}}}{ZeB} , \qquad ( 1 )$$

where M, Z, Wᵢ—are the mass, charge, mean energy of fast ions, kᵣ—is a coefficient taking into account the ion multiple reflection from the layer, Kᵢ=Iᵢ/Iₑ˜0.1, and in a plane parallel to a magnetic field, the layer coincides with a magnetic field lines.

Some publications indicate that the plasma flux is propagated into a solid angle lower than 2π, ˜2π/3. In this case we can analogously get the layer equation in the form:

$$r = {r}_{o 1} {sin}^{2} \frac{α}{2} , \\ ð {er}_{o 1} = 1.8 {r}_{o}$$

[symbol]

∂e rₒ₁=1.8rₒ. At B=20 mT, W=50 eV, Z=1, M=12 a.e.m., kᵣ=2 and Kᵢ=0.1 we get rₒ=1.75 cm, rₒ₁=3.25 cm.

In the typical arc sources of plasma with the graphite cathodes, an electron current of 150-500 A is emitted from 2-8 cathode spots (the mean current from one spot is 60-90 A). The cathode spots are located at the same force line of the transverse magnetic field [18].

In the ultimate case of the cathode spots uniformly located along the homogeneous magnetic field, one can get the current layer equation similar to (1):

$$r = {r}_{oN} {sin}^{2} \frac{α}{2} , \\ ð {er}_{oN} = 1.3 {r}_{o 1} .$$

[symbol]

∂e r_{oN}=1.3 rₒ₁.

The Hall layer is “attached” to the cathode spot takes the characteristic position in space independently of the anode position, thereby determining the reflection direction of ions from the Hall layer (FIGS. 1B, 1C).

To avoid almost full losses of the plasma related to its escape along a magnetic field it is offered to use the magnetic field of the arch shape produced by poles of a magnet, disposed with two sides of the cathode (FIG. 1C).

The calculations similar given in operation [18] give value of a cardioid radius in 2-2.5 times greater, than in the homogeneous magnetic field and the shape of a curve of the electron drift, shown on FIG. 1C. Thus, the arched magnetic field enables not only decrease the loss of plasma along the magnetic field but also to increase the ultimate length of the Hall reflecting layer.

The arc discharge can only exist if the anode is located on the way of the drift of electrons, i.e. is intersected with the cardioid (FIGS. 1B, 1C). In this case, the farther from the cathode spot is anode, the larger number of ions is reflected from the Hall layer, i.e. the higher is the plasma transport efficiency. In the ultimate case, at αₘₐₓ=π (FIG. 1B), all the ions should be reflected from the Hall layer. On the other hand, the farther from the cathode spot is anode, the higher is voltage at the current layer since this voltage increases with the angular coordinate α:

$$U = 〈 {E}_{⊥} 〉 h = \frac{{W}_{i}}{Z \cdot e} \cdot {sin}^{2} \frac{α}{2} \qquad ( 2 )$$

The discharge gap voltage is increasing by approximately the same value. The total voltage at the discharge gap in the presence of the transverse magnetic field will be equal to U_{AK}=U_{arc}+U ,where U_{arc}—is the discharge gap value with no transverse magnetic field.

With the higher voltage at the discharge gap U_{AK}>>U_{arc}, maintenance of a stable arc discharge can turn to be rather complicated.

The high voltage leads to significant plasma electron heating, and subsequentially to significant negative self-biasing of the substrate, and hence to high energy of the depositing ions.

Theory and experimental results has shown a possibility to utilize the effect of ion reflection from the Hall layer for filtration of an arc discharge plasma flow in the transverse arched magnetic field from macroparticles and steam and also for obtaining the intense clear fluxes of fast ions compensated for by electrons.

In view of the aforesaid, an object of the present invention is creation of a small-sized source of filtered cathodic arc plasma with transversal magnetic field of arched form used first of all for deposition of qualitative diamond-like coatings (DLC) at that eliminating transfer of macroparticles into deposition area at considerably increased plasma transport efficiency.

### SUMMARY OF THE INVENTION

The mentioned object is achieved by a proposed technical solution, including a source of filtered cathodic arc plasma with transversal magnetic field (filtered ion source). The proposed source is based on a novel method, developed for creation of a stable current Hall layer in a vacuum arc discharge in transversal magnetic field, characterized by the following features:
in the anode-cathode space by means of permanent magnets or electromagnets a transversal magnetic field of arched, toroidal or dome shaped form is created, which is directed parallel to the cathode's surface, perpendicular to retrograde movement of cathode spots and perpendicular to direction of plasma flux from the cathode spots, at that the said magnetic field in the anode-cathode spacing is reduced at increase of a distance from cathode, yet remaining above 40-60G, the force lines of magnetic field are concentrated near the poles and obtain a form of circular arc or ellipsoidal curve,
after initiation of the vacuum arc, a vacuum arc discharge is triggered, in which at a said form of magnetic field there are created the conditions for formation of current-carrying Hall layer on boundary of cathode plasma of the vacuum arc, which in one projection coincides with direction of the magnetic field, and in another projection has a form similar to a cardioid, that enables to obtain the most full reflection of ions in electric field of the Hall layer directed to the area of workpieces for coating deposition,
distance between anode and cathode is approximately equal to radius of a cardioid, and the anode is shifted to direction of electron drift in the Hall layer, it has orientation, at which a discharge current, running along the anode in form of a strip, stem or structure of strips, creates an additional magnetic field, directionally coinciding with a magnetic field, formed by means of constant magnets or electromagnets, that allows to prolong the Hall layer, and thus to increase the number of ions reflected from the Hall layer in the area of deposition, ie. ultimately increase the plasma transport efficiency,
stability of the vacuum arc discharge is achieved by the fact that cathode spots travel along the effective area of cathode and are retained on it either during working pulse or during all phase of arc discharge operation, owing to the fact that the said magnetic field, having an arched, toroidal or dome shaped configuration, forms only an arched configuration near the effective area of cathode,
two or more layers of protective screens of molybdenum, located under a floating potential and isolated one from another, cover all inactive surfaces of cathode, that enables to eliminate occurrence of parasitic arc discharges shunting the basic arc discharge, that, ultimately, provides stability of vacuum arc discharge,
on the surface of magnetic poles the plates of ceramics or porous ceramics are installed, that allows to avoid reduction of electric field in the current-carrying Hall layer caused by longitudinal and transversal shorting of the current-carrying Hall layer, i.e. ultimately increase stability of arc discharge and plasma transport efficiency,
increase of no-load voltage of power source of the vacuum arc discharge to 200-250 V compared to 40-70 V in a conventional arc discharge with a longitudinal magnetic field or without a field makes it possible to provide a stable arc discharge with the current-carrying Hall layer, proposed according to the present invention, since an operating voltage in the discharge gap is 70-100 V.

In the basic embodiment a proposed ion source with filtered arc discharge plasma in arched transversal magnetic field includes a cathode from consumable material, trigger device of the vacuum arc, system of protective screens, magnetic system and anode, imbedded in the vacuum chamber, which is capped from one end and open from another end for the area, where the workpieces for coating deposition can be mounted.

The aforesaid cathode is mounted in such a way as its so-called effective area, on which cathode spots are represening as a source of cathodic plasma, is turned by its face side to a capped end of the chamber, out of sight from the area, where the workpieces for coating deposition can be placed.

The above-mentioned magnetic system creates a magnetic field, directed across the cathodic plasma and parallel to the mentioned effective surface of cathode, and forms an arched configuration, owing to which a Hall layer is generated on plasma boundary, reflected from which the ions can change their trajectory so, that can travel from the said effective surface of cathode to the area, where the workpieces for coating deposition are placed.

The anode is made in form of narrow strips (sections) or stems bent and directed so as to let the discharge current, running in these sections, create a magnetic field, guided in the same direction that a magnetic field of the mentioned magnetic system.

The source is intended for operate in a pulse mode. During pulse operation the mentioned cathode spots have to make a retrograde movement in a transversal magnetic field of arched configuration from the place of ignition on one end of cathode to another end of cathode, where a current-carrying electrode is placed.

In another embodiment according to the present invention the proposed filtered ion source includes:
two or more cathode units arranged symmetrically on a circle and placed in a vacuum chamber capped from one end and open from another end for area, where the workpieces for coating deposition can be mounted;
at that the cathodes are connected to the same electric lead, and the arc discharge is triggered in turn on each cathode;
the divided anode is located in center of the chamber on an axis of symmetry so, as the plasma flux from each cathode changes its direction in arched magnetic field, as well as in magnetic field of a current, running along one of the anode's sections.

The aforesaid cathode unit consists of a cathode from consumable material (metal or graphite) and magnetic system. The cathode and magnetic system, creating a magnetic field, are identical to that described in the first embodiment of filtered source with arc discharge.

Similar to that in the first embodiment, the mentioned effective surface of cathode from consumable material “looks” in other side from deposition area, at that the ions being reflected from the Hall layer change their trajectory so, that they can travel from the said effective surface of cathode to the area, where the workpieces for coating deposition are placed, whereas undesirable macroparticles, which are unaffected by magnetic or electrostatic forces, cannot reach the workpieces.

As a matter of principle the cathode units can be arranges in pairs side by side or at an angle one to another.

In third embodiment the proposed filtered ion source can be manufactured, in general, similar to the second one, though
the cathode unit is arranged on the angle of less than 90° to the chamber's axis (i.e. at small angle to horizontal plane), and
additionally, the source outside the vacuum chamber has electric coil, which creates an axial magnetic field, and by means of which focusing of plasma flux is being intensified and corrected.

In forth embodiment the proposed filtered ion source can also repeat, in general, the second embodiment according to the present invention:
at that the cathode unit is arranged on the angle of less than 45° to the chamber's axis (i.e. under a major angle to horizontal plane);
the cathodes are connected to individual current lead wire;
the arc discharge is triggered in turn in each cathode;
the electromagnets and cathodes are connected to power supply in series;
and, additionally, the source outside the vacuum chamber has one or more electric coils, which create an axial magnetic field, by means of which focusing of plasma flux is being intensified and corrected.

In fifth embodiment the filtered ion source, intended for coating deposition inside tubes and/or cavities in a stationary mode or quasi-stationary state of arc discharge, includes:
the cylindrical cathode, located on axis of the source;
the anode in form of a squirrel cage, surrounding the cathode;
the constant magnet, located inside the cathode and creating a barrel magnetic field;
form and turning angle of the cage vanes are selected so as the surface of workpieces for coating deposition should be outside line-of-sight coverage from the cathode spots, and the major trajectories terminate on the covered surfaces.

Current of the arc discharge, running along the vanes, creates a magnetic field parallel to the vanes' surface. This field is sufficient for magnetizing the electrons that enables to reflect ions coming to the surface at a small angle.

In sixth embodiment the source of filtered arc discharge plasma with a conical cathode and toroidal magnetic field, intended to operate in a stationary mode or quasi-stationary regime, includes:
the conical cathode, located on source's axis, equipped with trigger device for vacuum arc, cooled current-carrying unit, cylindrical screen;
the magnetic system, creating a toroidal magnetic field in the cathode area;
the anode is made in form of truncated cone, divided into strips by grooves;
at that the transverse direction of magnetic fields of the anode is perpendicular to direction of magnetic field of the constant magnet near the cathode surface.

### BRIEF DESCRIPTION OF THE DRAWING.

The drawings below are given to illustrate the present invention, where

FIG. 1A is a schematic axonometric view of Geometry of Hall layer of a vacuum arc in a transverse magnetic field,

FIG. 1B is a view of Hall current layer and reflection of fast ions in a transverse magnetic field,

FIG. 1C is a schematic axonometric view of a source of filtered vacuum arc plasma with arched magnetic field,

FIG. 1D is interaction of a Hall layer of vacuum arc with anode in the proposed source of filtered plasma of vacuum arc,

FIG. 1E is influence of anode on magnetic field in the space between the cathode and anode,

FIG. 2A is a schematic axonometric view of a cathode unit,

FIG. 2B—idem in section,

FIG. 3A is of the source of filtered plasma of vacuum arc with a number of cathodes and a divided anode,

FIG. 3B—idem with cathodes, arranged at a small angle to horizontal plane,

FIG. 3C—idem with cathodes, arranged at greater angle to horizontal plane,

FIG. 3D is schematic axonometric view of a source fragment with two cathode units arranged in series and at an alternate angle of one to another,

FIG. 4A is schematic plane cross-section view of the source of filtered plasma of vacuum arc with cylindrical cathode and barrel magnetic field,

FIG. 4B is schematic radial section view of the source of filtered plasma of vacuum arc with cylindrical cathode and barrel magnetic field,

FIG. 5A is schematic plane cross-section view of the source with a conical cathode and toroidal magnetic field (with average disposition of plasma flux in the source according to time),

FIG. 5B is schematic side plane cross-section view of the source in FIG. 5A (illustrating a Hall layer and trajectory of ions in plane, passing through a cathode spot and parallel to the drawing),

FIG. 5C is schematic radial section view of the source of filtered plasma in FIG. 5A and FIG. 5B (illustrating an instant disposition of plasma flux in the source and its interaction with anode).

### DETAILED DESCRIPTION OF THE PREFERRED EMBODIMENTS

The present invention characterizes to a novel source of filtered cathodic arc plasma; in the source a transversal magnetic field of an arched form so that to develop a compact and efficient macroparticle-free plasma source with high throughput deposition.

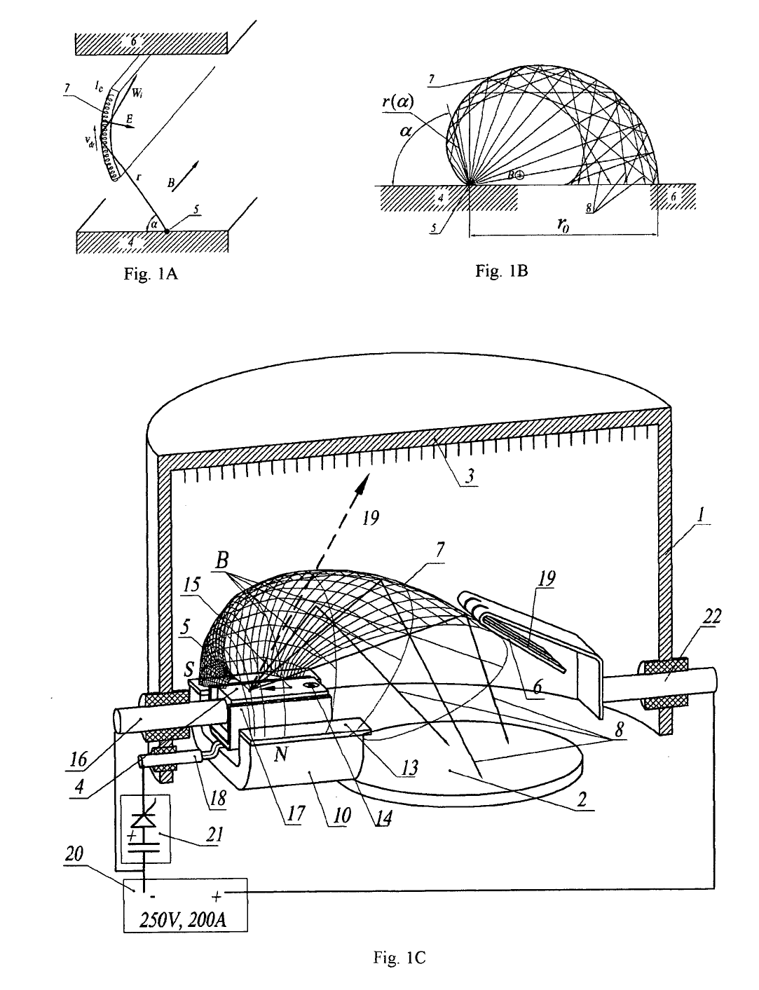

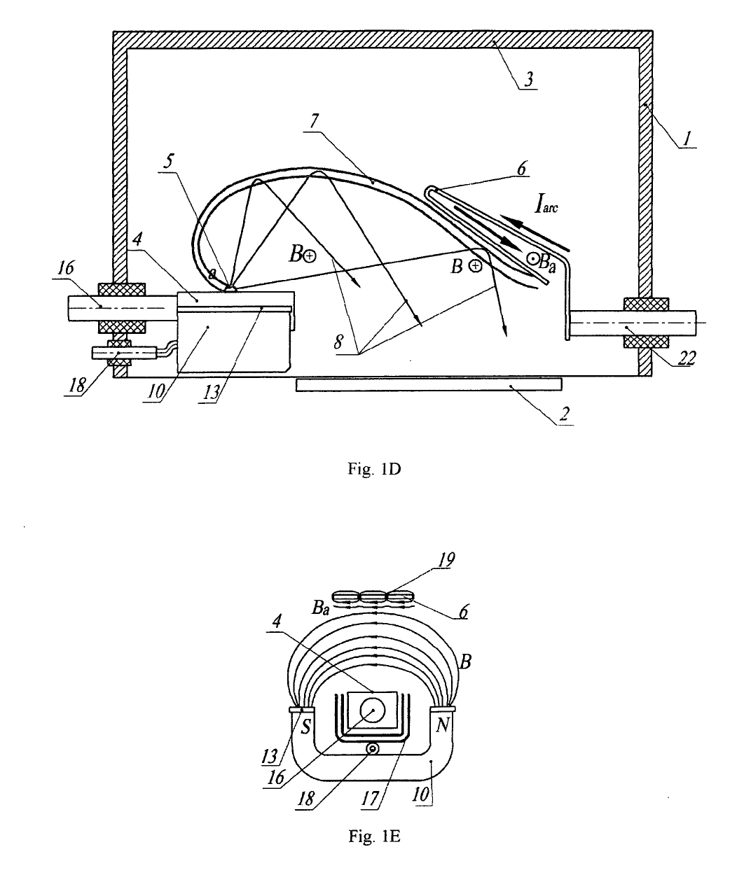

The basic embodiment of an ion source is shown in FIG. 1A, where vacuum chamber 1 and area 2 are illustrated schematically. The vacuum chambers for cathodic arcs are well-known in practice, therefore components and design of the chamber are not given here. The details (workpieces) for producing deposition (diamond-like coating) are arranged in area 2 and can be mounted in a holder or fastening and to move in said area for providing coating uniformity and high throughput of workpieces for coating deposition. Vacuum chamber 1 is capped at one end by an cover 3, equipped with partitions or other elements of more complicated structure to prevent macroparticles reflection in direction to area 2.

The vacuum arc discharge is sustained between cathode 4, on which cathode spots 5 are formed and produce cathode plasma jets, and anode 6 (FIGS. 1C, 1D).

The vacuum arc discharge in transversal magnetic field B is characterized by occurrence of Hall layer 7 on boundary of the cathode plasma of a vacuum arc and thus the plasma boundary in one direction coincides with direction of a magnetic field B, and in other projection has a cardioid-like shape.

The Hall layer is characterized by an electric field, which is perpendicular to magnetic field, at that the arc current transfers from cathode to anode only in Hall layer on boundary of plasma by electrons drifting in crossed fields. Therefore further a Current-carrying Hall Layer term is used in the patent application. An arc discharge can exist only if anode is present on drifting path of electrons, therefore anode 6 is located within this boundary layer.

Ions 8, reaching boundary layer 7, are reflected by an electric field, whereas marcroparticles 9 pass through the boundary and thus move away from plasma, since, unlike the electrons and ions, marcroparticles 9 flying from the cathode 4 are not strongly affected by magnetic or electrostatic field in the Hall layer, and they cannot make an abrupt turn required to reach area 2. Instead, of the marcroparticles collide with housing 1 or cover 3 and are thereby removed from the ion stream. The reflected ions 8 are utilized for a coating on a substrate which is placed in area 2, where there is a straight line between it and the Hall layer, but no straight line between the substrate and the cathode surface.

Creation of a stable Hall layer and prevention of plasma's leaving along a magnetic field is possible only in case of an arched form of transversal magnetic field. An arched magnetic field is formed by a constant magnet 10 with poles 11 and 12, arranged on both sides of cathode.

On the ends of magnet the plates of ceramics 13 are installed to exclude longitudinal and cross shorting of the current-carrying Hall layer, since an electron current along a magnetic field can destroy electric field in the Hall layer and impair stability of vacuum arc.

In the process of operation the ceramics surface turned to the Hall layer will be coated by a coating of cathodic material. To prevent this coating become conductive, it is advisable to use a high-porous ceramics. Presence of surface enables to keep the ceramics surface non-conducting for a long time, as deposition is produced in one direction.

In the event a graphite cathode is utilized, simple ceramics can be used, as a graphite coating deposited during discharge possesses diamond-like properties, i.e. low conductivity.

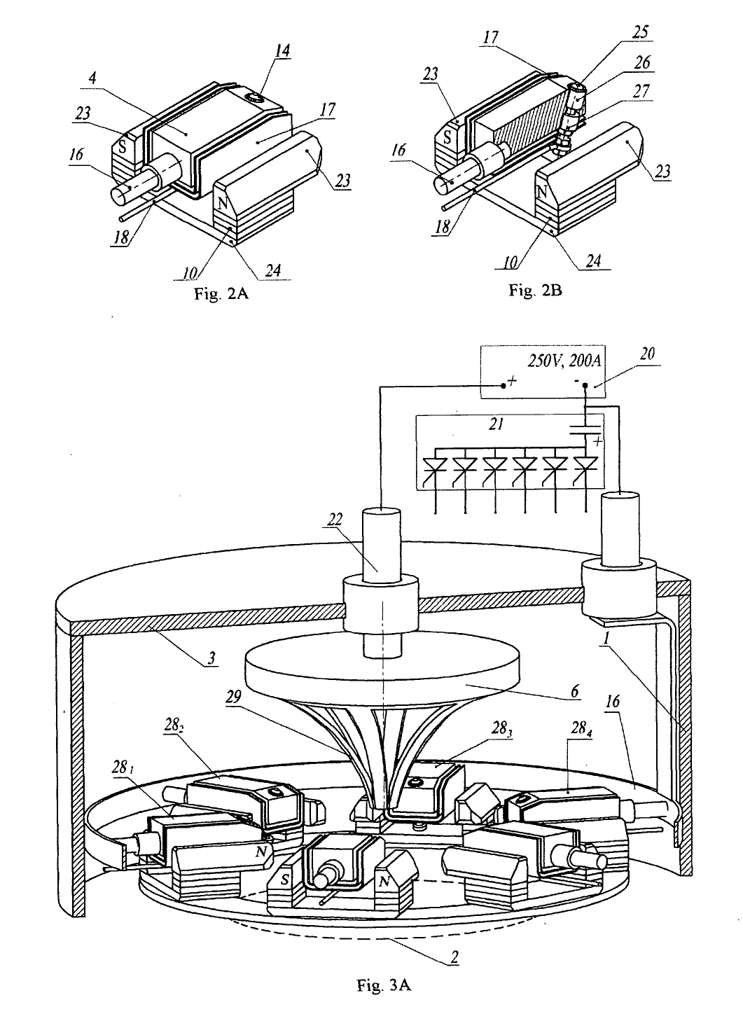

The cathode's length is chosen from 1 cm to 5 cm. Arc discharge in the source is triggered by a starting ignition pulse of the trigger device 14 (FIGS. 1C, 2A). During pulse of the arc discharge cathode spots 15 (FIG. 1C) make a retrograde travel along an effective surface of the cathode 4 across a magnetic field from the triggering place 14 in direction of the current outlet 16 (FIGS. 1C, 2A, 2B). An average time of retrograde motion of the cathode spots from the triggering place to the opposite end of cathode is equal to operating pulse duration.

The cathode spots, due to an arched form of magnetic field, travel, mainly, in the middle band of cathode and do not transfer beyond the bounds of the cathode effective surface. Screens 17 (FIG. 1C), situated under a floating potential, force the cathode spots to be only within the cathode effective surface and thereby to protect the cathode inactive surfaces against an accident penetration of the cathode spots on them.

The principle of operation of vacuum arc trigger device 14 is similar to electron disruption on ceramics surface. These devices are well known in the art (see work [20]), therefore there details are not described in the present patent application. Current-carrying electrode to the trigger device is executed via a vacuum inlet 18 (FIGS. 1C, 1D, 2A, 2B).

The anode 6 has a flat inverse segment bent in direction from cathode and down, which is divided into longitudinal sections 19 (FIGS. 1C, 1E). It was done to enlarge stability of discharge and to increase plasma transport efficiency. Behavior of current layer near the anode 6 depends on configuration of magnetic field Bₐ in its proximity (see FIG. 1D), which to great extent is formed by a current flowing on anode. A cross direction of magnetic fields of the anode current Bₐ in proximity of anode coincides with direction of magnetic field B of constant magnets near the surface of cathode (see FIG. 1C). Electron current of arc in the Hall current layer flows in general to the end of inverse segment, and further flows back along this segment and then right on the main part of anode. Owing to this fact the Hall layer can be extended, and, as a result of this, the number of ions reflecting from the Hall layer to deposition area 2 will be enlarged, i.e. the plasma transport efficiency will be increased. Longitudinal sections in the inverse segment of anode provide uniform distribution of current in width, eliminate distortion of total magnetic field under it and loosen deformation of field with time.

Geometrical dimensions of the plasma source depend on value of the used magnetic field, as the cardioid's radius is inversely proportional to the magnetic field value. It was also experimentally tested feasibility of stable Hall layer within range of B=0.005÷0.05)T, that corresponds to value limits of the cardioid's radius (80÷8) mm.

Thus, a real value of characteristic dimensions of the described source is within (18-160)mm. Operating voltage on vacuum arc in the arched transversal magnetic field reaches 100 V at no-load voltage of 250 V, whereas these values are equal to 20V and 60V, correspondingly, for conventional vacuum arcs without magnetic field or in a longitudinal magnetic field. Therefore knowledge and skill of designing accumulated during operating conventional vacuum arcs appeared to be insufficient for the given construction. Coming of cathode spots into inactive surfaces of cathode results in occurrence of a parasitic arc discharge along magnetic field and in ceasing of basic discharge. To provide the construction with a safe protection, it was undertaken a number of additional measures, which enable avoiding occurrence of parasitic arc discharges, shunting the basic discharge: in particular screens 17, which completely cover the cathode surface, leaving open only the effective surface, are made twofold from molybdenum; besides screens, there is also the whole magnetic system under floating potential.

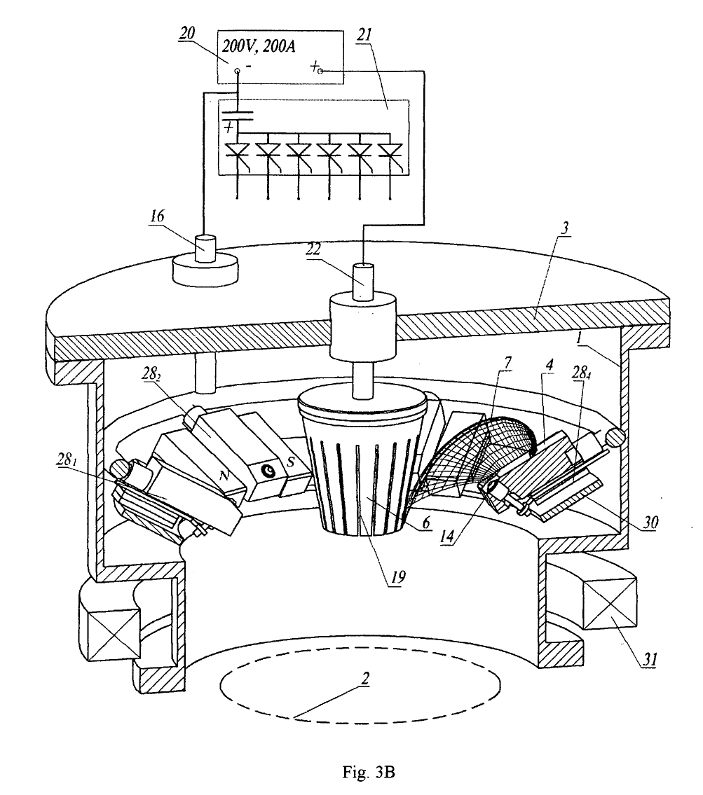

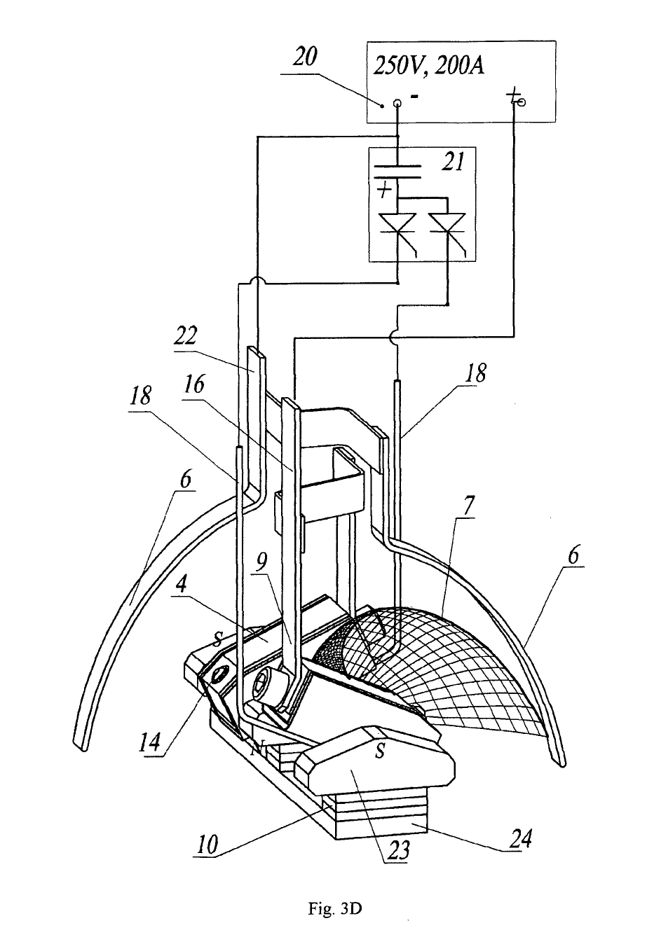

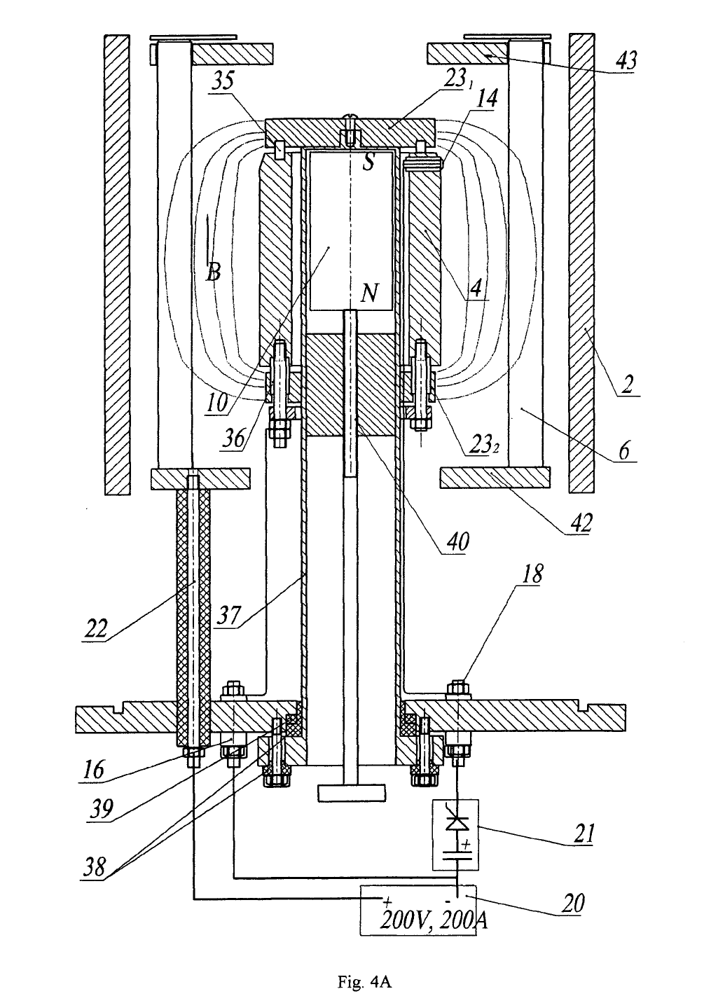

A power supply unit for arc discharge (FIGS. 1C, 3A, 3B, 3C) consists of a rectifier 20, having no-load voltage of 250 V and current of from 100 to 300 A, and a power supply unit 21 for vacuum arc ignition device (trigger device 14 in FIGS. 1C, 2A). The power supply unit of arc discharge is connected to the plasma source via hermetic current outlets 16, 18, and 22 (FIGS. 1C, 1B).

Embodiments of the proposed sources of filtered arc discharge plasma, including two or more cathode units, arranged symmetrically on a circle and installed in vacuum chamber 1, closed from one end 3 and open from another end for the area 2, where workpieces for coating deposition can be mounted, are shown in FIGS. 3A, 3B and 3C.

The cathode unit is a set of components (elements) described in the basic embodiment. The cathode unit (FIGS. 2A, 2B) includes cathode 4 of consumable materials; molybdenum screens 17, isolated one from another and from all other components and being under floating potential during discharge; constant magnets 10; magnetic poles 23 and magnetic core 24. The device for ignition arc discharge (FIG. 2A) operates as an electron disruption on ceramics surface. At feeding an ignition pulse to electrode 25 (FIG. 2B), an electron disruption on surface of the insulator 26 takes place, initiating an arc discharge. Insulator 27 serves for purpose of apparatus mounting.

Mentioned cathode units 28 (FIG. 3A) of the considered embodiment of source are used for mounting the plasma source, shown in FIG. 3A, with orientation of plasma flux along the axis of chamber 1 for depositing coating on various workpieces (parts and units) located below the chamber. Cathode units 28₁-28₆ are arranged symmetrically on a circle. All cathodes are connected to one current outlet 16 (FIGS. 3A, 3B) of power supply unit 20 and are triggered during operation in turn from a triggering unit 21. Such design enables to have large reserve of coating material, as well as allow loosening thermal behavior of cathodes, because in each cathode the interval between operating pulses increase in six times.

Central anode 6 consists of sections 29, which reproduce the boundary form of plasma (cardioid) at the cathode, opposite which it is located. Around each section of the central anode a magnetic field is formed during a discharge current running in it. Direction of magnetic field of anode coincides with the direction of constant magnets.

In principle (in some specific cases) the cathode units can be arranged nearby and placed at an alternate angle of one to another (FIG. 3D).

In embodiment sowed in FIG. 3A area 2 with workpieces for coating deposition can be arranged at a distance maximal close to effective surface of cathodes, this enables producing a macroparticles-free high density flux of metal or carbon plasma on the surface of workpieces. In some cases it is advisable to use an embodiment, in which area 2 containing workpieces for coating deposition is arranged at a remote distance from the plasma source. In this embodiment (FIG. 3B) the cathode units can be mounted at the angle to the chamber's axis of less than 90°. This, to some extent, facilitates the arc discharge mode and enables operating at no-load voltage of 200 V. In this embodiment electric coil 31 serves to form a plasma flux coming in direction of workpieces for coating deposition. All cathodes are connected to the same outlet 16 of power supply 20 and are triggered during operation in turn by a triggering unit 21. Central anode 6 is divided into sections 19. Around the nearest to operating cathode sections a magnetic field is formed during a discharge current running along them. Direction of magnetic field of the anode's sections coincides with direction of constant magnets (as in embodiment in FIG. 3A).

FIG. 3C illustrates an embodiment of the source of filtered arc discharge plasma with two or more cathode units, arranged symmetrically on a circle, placed at a remote distance from the workpieces for coating deposition, or comparatively small aperture of plasma flux output. In this embodiment the cathode units can be arranged at the angle to the chamber's axis about 45-30°. This enables operating at no-load voltage of 180 V. In this embodiment a set of electric coils 31 serves to form a plasma flux coming in direction of workpieces for coating deposition. In this embodiment electromagnets 32 are used to exclude impact of magnetic field of neighboring cathode units due to close arrangement.

Effective voltage pulses are fed to the cathode units 28₁÷28₆ in turn. The cathodes are connected through individual current leads to one power supply 20 and triggered in turn by a set of triggers 21. To create an arched magnetic field, electromagnets 32 (switching in turn with operating cathodes) are installed. Electromagnets are used in this embodiment to exclude impact of magnetic field of neighboring cathode units due to close arrangement. Electromagnets 32 and magnetic cores 33 are installed outside the vacuum space. Electromagnets and cathodes are connected in series to a power supply. At triggering of one of cathodes the arc discharge and magnetic field near this cathode occur simultaneously. A series connection, creating a back coupling of magnetic field with current discharge, facilitates triggering of arc discharge and provides stability of vacuum arc with a Hall layer during operating pulse. A variable resistor 34 is used for adjusting a back coupling. The central anode 6 has a form of thin rod. A magnetic field is formed around the rod during discharge current running in it. Direction of magnetic field of the anode coincides with direction of field constant magnets.

FIG. 3C FIG. illustrates an embodiment of the source of filtered arc discharge plasma with two cathode units, arranged parallel one to another and oriented so as the plasma flux from cathodes is guided to different directions.

In this embodiment the cathode units can be arranged at an angle to horizontal line of about 45-30°. This enables avoiding the cathodic material coming from one cathode to another. Such arrangement of cathodes can be used, when presence of traces of other cathode material during coating deposition is forbidden. For example, during deposition of DLC coating the occurrence of titanium traces, used for coating the intermediate layers, is inadmissible. The cathodes 4 are connected to one power supply 20 and triggered in turn by a set of triggers 21.

The area of workpieces' s location is arranged in bottom part of the chamber. In top part of the chamber the means for entrapping macroparticles can be installed.

The anode 6 has a form of plates bent in the shape of a Hall layer. A magnetic field is formed around the plates during discharge current running in them. Direction of magnetic field of the anode coincides with direction of constant magnets.

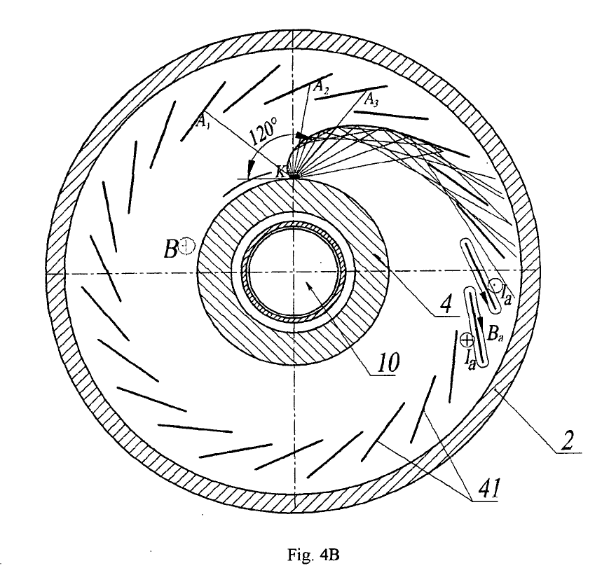

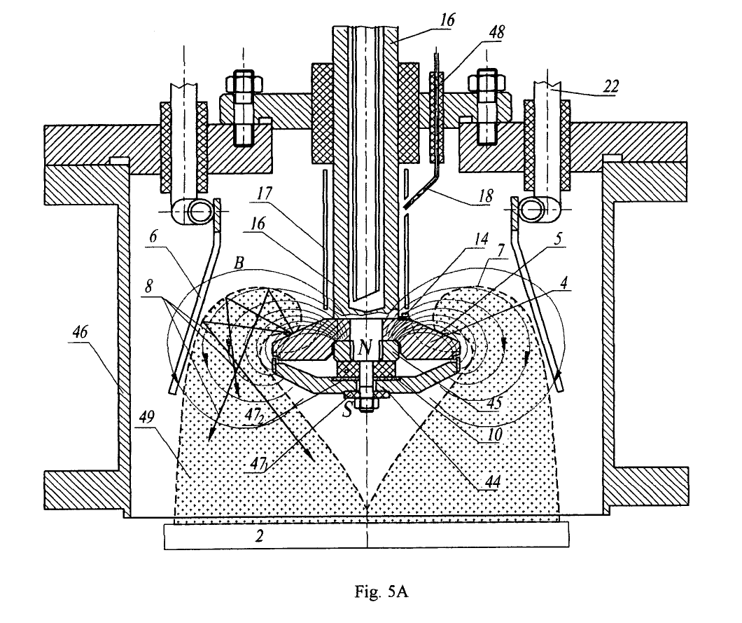

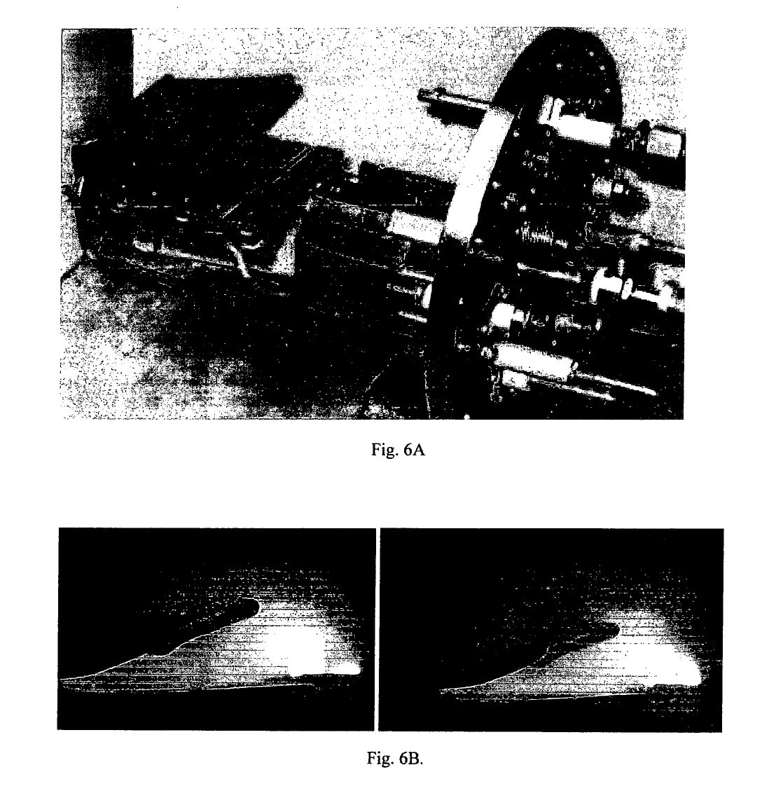

FIG. 4A and FIG. 4B illustrate an embodiment of the source of filtered plasma of vacuum arc with cylindrical cathode and barrel magnetic field.

The source is installed on a flange, connected to the vacuum chamber, not shown in drawing.

A cylindrical cathode 4 is arranged on axis of axial-symmetric system and is surrounded by the anode 6 in form of a squirrel cage. A barrel magnetic field is created by a constant magnet 10, installed inside cathode, and annular magnetic poles 23₁ and 23₂, located in both ends of cathode. The cathode is isolated from the poles by means of ceramics inserts 35 and 36. The cathode is connected to a minus terminal of the power supply 20 via a bushing insulator 16. In the top part of cathode a vacuum arc trigger device 14 is installed. The principle of operation of this device 14 is similar to that of electron disruption on ceramics surface. These devices are known in the art, therefore their components and design are not given here [20]. Current lead to a trigger device is executed via a hermetical current lead-in 18. After discharge initiation the cathode spots 5 perform a retrograde motion along a circle on cylinder surface (effective surface of cathode). The barrel magnetic field sustains the cathode spots within effective surface.

The cathode unit (cathode 4, trigger device 14 and annular magnetic poles 23₁ and 23₂) is mounted on a stainless steel pipe 37, hermetically capped from one end and being under a floating potential. The packing elements, such as textolite rings 38 and rubber gasket 39, provide a vacuum pipe-to-flange joint without electric contact. Owing to this fact magnet poles will be under a floating potential and protect inactive surfaces of cathode from penetration of cathode spots.

A discharge can exist in a stationary mode. Duration and periodicity of operating pulses can be chosen depending on cooling conditions and deposition technological process requirements.

A cylindrical constant magnet 10 and a system of magnetic field regulation 40 are arranged inside the pipe cavity. It enables in automatic mode to achieve maximal output of ion stream to the surface of substrate 2 in area at changing form of cathode in the process of operation.

Current supply to the anode 6 is carried out via a hermetical current lead 22. Vanes 41 (FIG. 4B) fastened of discs 42 and 43 (FIG. 4A).

Shape and angle of vanes' turn (FIG. 4B) are selected so as the surface (in area 2) of substrate lies beyond the sight from the cathode spots, and at the same time the maximal number of ion trajectories terminates on the deposited surface. Macroparticles trajectories A1, A2, A3 (FIG. 4B) terminate on the vanes' walls. This enables to protect a workpiece against macroparticles and vapor at minimal losses of ion stream.

It should be noticed that ions, flying from a cathode spot at the angle of (0÷120)° to the surface (i.e. ⅔ of total amount of ions), reflect repeatedly from the Hall layer, slightly moving away from the Hall layer, and so almost all of them pass through the vanes. The remaining ⅓ part of ions partly pass through the vanes and partly come on the vanes at small angle to the surface.

The arc discharge current flows along the vanes and creates a magnetic field parallel to the vanes' surface. This field is sufficient for magnetizing the electrons that let the ions, traveling at small angle to the vanes' surface, reflect from the surface. To intensify this effect the vanes are coupled in pairs on the top and fastened to the isolator on top disc 43. A contact with a bottom disc 42 is performed by one vane of the pair. Owing to this fact the current flows in the neighboring vanes in different directions, as in a loop, and in this case a magnetic field Bₐ of current Iₐ of neighboring vanes has the same direction, this provides better conditions for losses-free plasma flux flowing between the vanes.

Dimensions of the source, determined by an external diameter of anode, can vary within 30-250 mm and, respectively, minimal diameter of the inner cavity for deposition should be 35 mm.

A power supply unit consists of a vacuum arc source 20, designed for operation in a quasi-stationary state at no-load voltage of 200 V and discharge current of 20-300 A; and a power unit for trigger device 21.

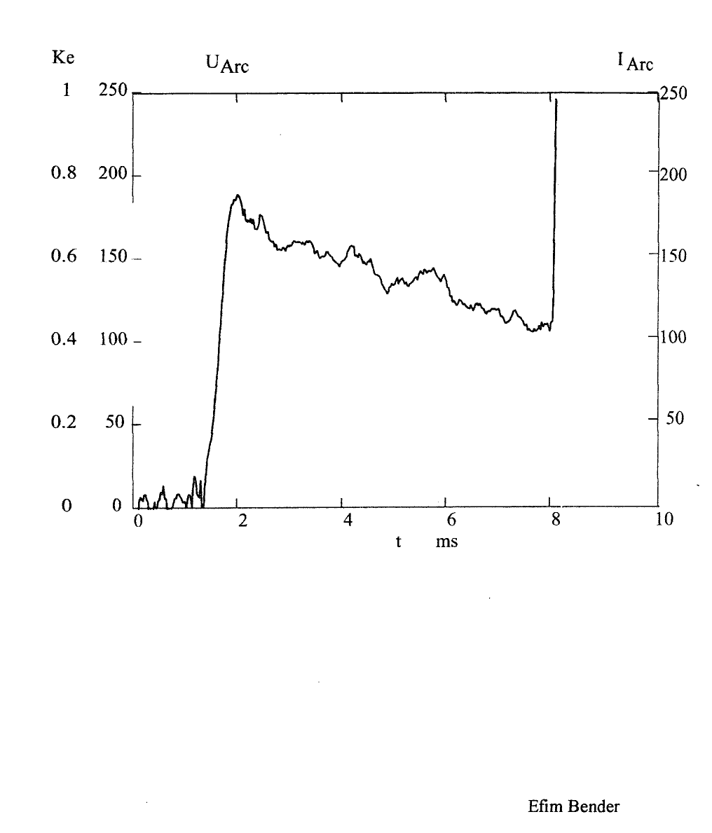

FIGS. 5A, 5B and 5C illustrate embodiment of the source of filtered arc discharge plasma with a conical cathode and toroidal magnetic field, intended to operate in a stationary mode or quasi-stationary regime.

The source of filtered arc discharge plasma is arranged on one flange and installed in the center of a cylindrical chamber 46, which in its turn is connected to a vacuum system, not shown in drawing.

The cathode unit includes a conical cathode 4, vacuum arc trigger device 14, cooled current-carrying electrode 16, cylindrical screen 17 and a magnetic system creating toroidal magnetic field in cathode area.

The magnetic system consists of an annular constant magnet 10, conical magnet pole 44 and annular pole 45. The pole 45 is also a screw, which fastens the cathode 4 to current-currying electrode 16 to create electric and thermal contact.

Ceramic washers 47₁ and 47₂ isolate the pole 44, that enables using it as a screen for protection of inactive surfaces of cathode 4 from the cathode spots hitting them.

The cathode spots 5 (FIGS. 5B, 5C) make a retrograde motion 15 in a circle. A toroidal shape of magnetic field B makes the cathode spots remain on effective conical surface of cathode. The Hall layer 7 in a toroidal magnetic field has more complicated configuration than that in an arched magnetic field, and reminds a cardioid in section only passing through a cathode spot and parallel to drawing of FIG. 5B. FIG. 5B shows location of plasma flux 49 in the source, averaged per one turn of cathode spots. Major part of ions 8 reflects in direction of workpieces placing in the area 2.

The principle of operation of the vacuum arc trigger device 14 is similar to electron disruption on ceramics surface. It is important to notice that the device is located in the area, from which the cathode spots are easily transferred in a toroidal magnetic field to effective surface of cathode and cannot return to the place of trigger device to destroy it.

Current supply to a trigger device is executed via hermetical current lead-in 18.

Anode 6 is made in the form of truncated cone divided into strips 19 by grooves (FIG. 5C). Behavior of current layer near the anode depends on configuration of magnetic field in its vicinity, which is formed by a current flowing on anode. A cross direction of magnetic fields Bₐ of the anode current is perpendicular to direction of magnetic field B of constant magnets near the surface of cathode. Electron current of arc in the Hall current layer flows, in general, to the bottom end of anode strip and further flows back along this strip. Owing to this fact, the Hall layer can be extended, and thus to enlarge the number of ions reflecting from the Hall layer to deposition area 2. Longitudinal sections in the anode provide occurrence of more intensive magnetic field only in the plasma flux area.

The embodiments described above relate to use of the present invention in a physical vapor deposition system using the cathodic arc. It is important to note that the present invention is by no means limited to deposition of materials on substrates, but rather, the macroparticle filtering at small distance from the cathode aspect of the present invention has several beneficial uses besides deposition or coating application.

For example, efficient macroparticle filtering enables an arc ion source to function as a high intensity electron source for heating workpieces prior to coating. Additionally, this space-saving high electron density source is able to be used for excitation and ionization of vapor produced by an auxiliary evaporation source. When operating such electron source, high intensity, and low energy electron streams are capable of being produced. This heating capability may be exploited as a means for vacuum degassing components, surface annealing or other vacuum heat treatments.

Besides, effective filtering of macroparticle allows this arc plasma source to function as ion source of a cathode material for further acceleration in devices of ionic implantation, ionic alloying or ionic etching.

Thus, the present invention is by no means limited to use as a deposition system, but rather any situation, where efficient filtering of macroparticles from ions is beneficial, can utilize the present invention.

Furthermore, the embodiments described below relate to all deposition systems using consumable cathode materials.

### EXAMPLE

A proof-of-principle demonstration Hall sheath plasma source designed, constructed and tested. The test device, illustrated in FIG. 6A, had the following characteristics:
2×4 cm cathode, of either graphite or Ti
Arched magnetic field, with a field strength in the range of 16-21 mT at the cathode surface
Interchangeable Cu strip anodes with various sizes, and the ability to adjust the anode position by bending.
A 5-element probe array, located below the cathode plane, so that plasma reaching it was bent through a trajectory of ˜180°.

The source was excited by a pulsed power supply, capable of supplying arc current pulses of up to 200 A, with a rise time of 0.2 ms, with a flat-top pulse of 7 ms duration. After preliminary experiments to establish the optimum operating conditions, the following was found:
The photographically observed plasma shape corresponded to that predicted in theoretical models. (FIG. 6B)
The arc voltage was 75-100 V.
The floating potential of the probe elements was negative −(50÷70) V relative to the cathode potential.
Optimum ion current to the probe was observed with a magnetic field of 18-21 mT.
Carbon ion currents of up to 16 A, corresponding to 6-8% of the arc current, were measured at the probes, which negatively biased to −(100÷150) V with respect to the cathode.
We have experimentally checked the influence of ceramic plates installed at the magnetic poles (FIG. 1C). We found out that with the ceramic plates, the arc discharge stability and plasma transport efficiency become better to 20-30%.

At the experimental arc source of carbon ions with the transverse magnetic field, the plasma transport efficiency up to 70% was achieved, that exceeds substantially the value obtained at the other types of arc sources. The best results have been obtained with the arch magnetic field optimized by its value and shape and also with the ceramic plates on the magnet poles and with the vacuum arc glowing rather stably. On a FIG. 6C it is shown: voltage on the discharge gap U_{Arc} and the discharge current I_{Arc} waveforms during a discharge with magnetic field B=17 mT. Also shown is the plasma efficiency

$${}_{-}^{}{K}{}_{e}^{} = \frac{{I}_{Σ}}{{I}_{Arc}} \cdot 10$$

Experimental results and especially measurements of the fast ion flows and pictures of the glowing inter-electrode plasma of the vacuum arc in the transverse magnetic field prove the formation of the Hall current layer.

These results demonstrate that the Hall sheath ion reflection principle can be used to construct an efficient, compact filtered cathode arc plasma source.

### LITERATURE

1. Sanders D. M., “Ion Beam Self-Sputtering Using a Cathodic Arc Ion Source”, J. Vac. Sci. Technol. A 6(3):1929 (1987)
2. Falabella S. et at., “Comparison of Two Filtered Cathodic Arc Sources”, J. Vac. Sci., Technol. A 10(2), March/April 1992, 394-397.
3. Anders S. et al, S-Shaped Magnetic Macroparticle Filter for Cathodic Arc Deposition”, IEEE Transactions of Plasma Science, vol. 25, No. 4, August 1997
4. D. A. Karpov, “Cathodic Arc Sources and Macroparticle Filtering”, Surface and Coating Technology 96 (1997) 22-33. (12 pages)
5. Kuhn et. al., “Deposition of Carbon Films by a Filtered Cathodic Arc” Diamond and Related Materials, No. 10, August 1993.
6. Martin, P. J, and A. Bendavid. “Ionized Plasma Vapor Deposition and Filtered Arc Deposition; Processes, Properties and Applications.” Journal of Vacuum Science & Technology A 17(4):2351-2359, July/August 1999.
7. Morozov A. I., and Lebedev S. V., Plasmaoptics, Boπpocbl Teop [symbol] πJIa3MbI. noπ peπ. M. A. JIeoHToB [symbol] 4a, BbIπ.8, ATOM [symbol] 3πaT. M., 1974, c.247.
8. Aksenov I. I. et al., Transport of Plasma Streams in a Curvilinear Plasma-Optics System, Sov. J. Plasma Phys. 4(4), July-August 1978, 425-428. (1978).
9. Welty Richard P., Rectangular vacuum-arc plasma source. U.S. Pat. No. 5,840,163, Dec. 22, 1995, U.S. C1. 204/192.38; Int. C1. C23C 014/32.
10. Falabella, et al., Filtered cathodic arc source. U.S. Pat. No. 5,279,723, Jan. 18, 1994; U.S. C1. 204/192.38; Int. C1. C23C 014/32.
11. Shi, Xu; et al., Cathode arc source with magnetic field generating means positioned above and below the cathode, U.S. Pat. No. 6,761,805, Jan. 25, 1999, U.S. C1. 204/192.38; Int. C1. H01J 037/32; C23C 014/00.
12. Anders at al., Filters for cathodic arc plasmas. U.S. Pat. No. 6,465,780, Mar. 31, 2000; U.S. C1. 250/298; Int. C1. B01D 059/44; H01S 049/00.
13. Sanders at al., Ion source based on the cathodic arc. U.S. Pat. No. 5,282,944, Jul. 30,1992; U.S. C1. 204/192.38, Int. C1. C23C 14/32;
14. Sathrum Paul E., Filtered ion source. U.S. Pat. No. 6,756,596, Apr. 10, 2002; U.S. C1. 250/426, Int. C1. H01J 027/14.
15. Aksenov I. I. at al., Arc plasma generator and a plasma arc apparatus for treating the surfaces of work-pieces, incorporating the same arc plasma generator. U.S. Pat. No. 4,452,686, Mar. 22, 1982; U.S. C1. 204/298.41. Int. C1. C23C 15/00.
16. Krzysztof Miernik at al; Design and performance of the microdroplet filtering system used in cathodic arc coating deposition. Plasmas & Ions (2000) 3, 41-51.
17. Krauss Alan. R., Filtered cathodic arc deposition apparatus and method. U.S. Pat. No. 5,902,462; Mar. 27, 1997. U.S. C1. 204/192.38.
18. Emtage P. R at al; Interaction Betwin Vacuum Arc and Transwerse Magnetic Fields with Application to current Limitation.//IEEE Trans. on Plasma Sci., Vol. PS-8, N. 4, 1980.
19. E. D. Bender and A. S. Krivenko. The Hall lay in the plasma of a vacuum arc in a cross magnetic field. “Applied physics” No. 5, 1999 (Rus. -“Prikladnaya Fizika”)
20. E. D. Bender. The electric-arc evaporator of the metals. Patent SU, No. 1812240 A1 C1. C23C 14/32, 1990.

What I claim is:

1. A cathode-arc source of metal/carbon plasma with filtration, in particular, for producing diamond-like coating on the surface of workpieces, comprising placed in a vacuum chamber opened from the side of said workpieces:
cathode, trigger device of vacuum arc, installed on the cathode, screens, anode and magnetic system, characterized in that
the cathode is made of a consumable material—former of coating on the workpieces, the effective surface of which is turned to a capped end of the vacuum chamber, and all cathode surfaces, except an effective one, are protected against cathode spots by a system of screens being under a floating potential,
the cathode is embraced by the constant magnet with poles on both ends of cathode for forming over the effective surface of cathode a transversal magnetic field of an arched shape to provide advent of a current-carrying Hall layer on the boundary of forming plasma,
the anode is made as a flat reverse segment, bent down backward to the cathode, in the form of longitudinal strips for increasing stability of arc discharge and plasma transport efficiency,
in the vacuum chamber bottom part being beyond the sight from the effective surface of cathode there is the area for deposition of specified coating on workpieces.

2. The cathode-arc source of claim 1, wherein said ends of poles of a constant magnet (magnets), embracing the cathode, are closed by isolating plates, preferably ceramics, for exclude longitudinal and cross shortening of current-carrying Hall layer, to facilitate stability of vacuum arc.

3. A cathode-arc source of metal/carbon plasma with filtration, in particular, for producing diamond-like coating on the surface of workpieces, comprising placed in a vacuum chamber, opened from the side of said workpieces:
cathode, trigger device of vacuum arc, installed on the cathode, screens, anode and magnetic system, characterized in that
at least two cathode units arranged at a definite angle to horizontal plane, creating in turn an arc discharge in each cathode,
each cathode unit includes a cathode made of material - former of coating on the workpieces, preferably from graphitic, with the effective surface turned to a closed end of the vacuum chamber, and all surfaces of each cathode, except effective one, are protected by screens against cathode spots,
trigger device of vacuum arc is installed on each cathode,
on each cathode a constant magnet with poles on both sides of cathode is installed for creating over the effective surface of cathode a transversal magnetic field of an arched shape to provide advent of a current-carrying Hall layer on boundary of forming plasma,
the anode is located in center of the vacuum chamber along the axis of symmetry so, that a magnetic field of current running along the anode and an arched magnetic field of constant magnets have the same direction,
in the vacuum chamber bottom part being beyond the sight from the effective surface of cathode there is the area for deposition of specified coating on workpieces.

4. The cathode-arc source of claim 3, wherein:
the cathodes with common current lead wire are arranged at small angle to horizontal plane;
the anode is made sectioned;
the source outside the vacuum chamber is additionally equipped with an electrical coil creating an axial magnetic field for alignment and focusing the plasma flux.

5. The cathode-arc source of claim 3, wherein:
the cathodes with individual current lead wire are arranged at large angle to horizontal plane;
the anode is made rod-shaped;
the source outside the vacuum chamber is additionally equipped with two electrical coil, creating an axial magnetic field for alignment and focusing the plasma flux.

6. The cathode-arc source of claim 3, wherein the cathode units are arranged in a circle.

7. The cathode-arc source of claim 3, wherein the cathode units are arranged nearby and at alternate angle of one to another.

8. A cathode-arc source of metal/carbon plasma with filtration, in particular, for producing diamond-like coating inside tubes and cavities, comprising arranged in the vacuum chamber:
cathode, trigger device of vacuum arc, installed on the cathode, anode and magnetic system characterized in that
the cathode is made cylindrical,
the constant magnet is located inside the cathode and together with annular poles create a barrel magnetic field to provide advent of a current-carrying Hall layer on the boundary of forming plasma, as well as to hold cathode spots on cylindrical effective surface of cathode during operating pulses;
the anode is made in the shape of squirrel-cage, the shape and turning angle of the cage vanes are selected so as the surface of the deposited tube/cavities were beyond the sight from the cathode spots, and the maximal number of ion trajectories terminates on the deposited surface.

9. A cathode-arc source of metal/carbon plasma with filtration, in particular, for producing diamond-like coating in a stationary/quasi-stationary regime on the surface of workpieces, placed in a vacuum chamber, opened from the side of said workpieces, comprising:
cathode, trigger device of vacuum arc, installed on the cathode, screens, anode and magnetic system, characterized in that
the cathode is made of consumable material—former of coating on the workpieces, has a conical effective surface, which is turned to a closed end of the vacuum chamber, and is installed along axis of the source with vacuum arc trigger device, current-carrying electrode and cylindrical screen;
the magnetic system for creating a toroidal magnetic field consists of an annular constant magnet with one annular magnetic pole and the other conical magnetic pole, which, simultaneously, serves as a screen protecting the inactive surfaces against the cathode spots penetration.
the anode, embracing outside the adjacent to the cathode area, is made in the shape of truncated cone, divided into strips by grooves, with provision transverse direction of magnetic field of the anode current perpendicular to direction of a toroidal magnetic field near the cathode surface;
in the bottom part of vacuum chamber, arranged beyond the sight from a conical effective surface of cathode) there is an area for placement workpieces for coating deposition.

10. A method for forming current-carrying Hall layer in vacuum arc discharge in a arched transversal magnetic field in the cathode-arc source of metal/carbon plasma with filtration, including the following stages.
increase of no-load voltage of the power source of vacuum arc discharge to 200-250 V;
creation in the cathode-anode interelectrode space of an arched magnetic field by means of constant magnets/electromagnets, with direction of magnetic field parallel by to the cathode surface, perpendicular by to retrograde movement of cathode spots and perpendicular by to the plasma flux moving from cathode spots, with the force lines of magnetic field being concentrated near the poles and having a shape of circular arc/ellipsoidal curve, for creation of conditions for advent of a current-carrying Hall layer on boundary of cathodic plasma of the vacuum arc, which in one projection coincides with magnetic field direction and in another projection has a cardioid-like shape,
creation of additional magnetic field in said interelectrode space near to the anode, coinciding with magnetic field direction of said constant magnets, by means of shaping the anode of the shape, for example strip/structure of strips with a definite orientation of anode towards the plasma flux, with provision of high transport efficiency of plasma.
